(19) United States
(12) Patent Application Publication
(10) Pub. No.: US 2022/0050345 A1
(43) Pub. Date: Feb. 17, 2022

(54) DISPLAY PANEL AND METHOD OF RESTORING VERTICAL DARK LINES OF DISPLAY PANEL

(71) Applicant: Shenzhen China Star Optoelectronics Technology Co., Ltd., Shenzhen (CN)

(72) Inventor: Mengyang LIU, Shenzhen (CN)

(21) Appl. No.: 16/605,570

(22) PCT Filed: May 17, 2019
(86) PCT No.: PCT/CN2019/087493

§ 371 Date: Oct. 16, 2019

(30) Foreign Application Priority Data
Apr. 19, 2019 (CN) 201910320459.2

(51) Int. Cl. G02F 1/1362; G02F 1/1333; H01L 21/768; H01L 27/12; B23K 26/21

(52) U.S. Cl. CPC G02F 1/136263; G02F 1/133345; B23K 26/21; H01L 21/76894; H01L 27/124; G02F 1/136295

(57) ABSTRACT

A display panel and a method of restoring vertical dark lines of a display panel are provided. The display panel has at least one fan-out trace with a double-decked conducting wire structure. The fan-out trace includes a first conducting wire and a second conducting wire stack-up. An insulating layer is disposed between the first and second conducting wires to insulate and space the first and second conducting wires. For the method of restoring vertical dark lines of the display panel, forming at least four welds at an equal interval on the fan-out trace to electrically connect the first and second conducting wires.

### BACKGROUND OF DISCLOSURE

### 1. Field of Disclosure

The present disclosure relates to the field of display technology, and more particularly, to a method of restoring vertical dark lines of a display panel.

### 2. Description of Related Art

With the development of display technology, flat-panel display devices such as liquid crystal display (LCD) devices possess advantages of high image quality, power saving, thin body, and wide application scope. Thus, they have been widely applied in various consumer electronic products, such as cell phone, television, personal digital assistant, digital camera, notebook, desktop computer, etc. and become the mainstream display devices.

Most of the liquid crystal display devices in the present market are backlit liquid crystal display devices, which include liquid crystal display panels and backlight modules. The working principle of the liquid crystal display panels is to locate liquid crystal molecules between two parallel glass substrates and to control the directions of the liquid crystal molecules to vary by whether or not applying voltages to the glass substrates so that the light of the backlight modules is reflected to generate images. Generally, a liquid crystal display panel includes a color filter (CF) substrate, a thin film transistor (TFT) array substrate, liquid crystals (LCs) sandwiched between the color filter substrate and the TFT array substrate, and a sealant frame.

In the liquid crystal display panel, an array substrate includes a display area and a non-display area. Gate lines and data lines, disposed criss-cross in the display area, are used to control each pixel in order to display images. A driving chip and fan-out traces connected to the driving chip are disposed in the non-display area. Gate driving signals and data signals are sent out from a control chip of a liquid crystal display device, and are transmitted respectively to the gate lines and the data lines on the array substrate through chip on film (COF). Display signals are provided through each of the fan-out traces for the display area. In order to reduce the non-display area and enlarge the display area, each of the fan-out traces is generally designed to gather toward the driving chip so that a fan-out area is formed.

Currently, the fan-out traces have two kinds of conducting wire structure, such as single-decked structure and double-decked structure. In a double-decked conducting wire structure, resistance of the fan-out traces can be reduced, and a signal loss can be reduced further. Thus, fan-out traces with the double-decked conducting wire structure are generally used on the array substrate. The double-decked conducting wire structure includes two conducting wires, one end of the two conducting wires in parallel is connected to a signal line, and the other end of the two conducting wires in parallel is connected to a terminal of the control chip. However, while the two conducting wires of the fan-out traces are fabricated in a practical manufacturing process, one of them may be broken due to film-forming foreign objects or other reasons, thereby causing impedance of the fan-out traces to increase and causing a loss of signals transmitted by the fan-out traces to increase, so that vertical dark lines occur in display images, and display effects are affected.

### SUMMARY

The object of the present disclosure is to provide a method of restoring vertical dark lines of a display panel, which can solve technical problems that impedance increases due to a broken single-decked conducting wire in fan-out traces with a double-decked conducting wire structure, thereby causing vertical dark lines to occur in display images, causing display effects to be affected, and causing a quality level of display panel to be reduced.

The object of the present disclosure is to further provide a display panel, which can solve technical problems that impedance increases due to a broken single-decked conducting wire in the fan-out traces with the double-decked conducting wire structure, thereby causing vertical dark lines to occur in display images, causing display effects to be affected, and causing a quality level of display panel to be reduced.

In order to realize the above objects, the present disclosure provides a method of restoring vertical dark lines of a display panel having at least one fan-out trace with a double-decked conducting wire structure, the at least one fan-out trace including a first conducting wire and a second conducting wire stack-up, an insulating layer being disposed between the first and second conducting wires to insulate and space the first and second conducting wires, one of the first and second conducting wires having a gap, the method including:

Forming n welds at an equal interval on the at least one fan-out trace, wherein the at least one fan-out trace is equally divided into n+1 line segments by the n welds, wherein the first and second conducting wires are electrically connected at a location of each of the n welds through the n welds, and wherein n is a natural number greater than or equal to four.

Four welds are formed on the at least one fan-out trace.

The n welds are formed through a laser-welding method.

The step of forming the n welds through the laser-welding method includes: illuminating, by a laser, the at least one fan-out trace, so that the insulating layer illuminated by the laser is staved in, and the first and second conducting wires illuminated by the laser melt to form the n welds in the insulating layer staved in.

Two ends of the first conducting wire are electrically connected to two ends of the second conducting wire respectively to form two ends of the at least one fan-out trace.

The display panel is divided into a display area and a joint area located at the outside of the display area, wherein a plurality of signal lines are disposed in the display area, wherein at least one pad for externally connecting a driving chip is disposed in the joint area, and wherein the plurality of signal lines include a plurality of gate lines and a plurality of data lines, which intersect with each other.

The at least one fan-out trace is disposed in the joint area, wherein one end of the at least one fan-out trace is connected to the plurality of gate lines or the plurality of data lines, and wherein the other end of the at least one fan-out trace is connected to the at least one pad.

The first conducting wire and the second conducting wire are both metal wires.

The first conducting wire and the second conducting wire are both wires made of aluminum.

The present disclosure further provides a display panel, made using the above method of restoring the vertical dark lines of the display panel.

The beneficial effect of the present disclosure is that, for the display panel and the method of restoring vertical dark lines of the display panel, provided in the present disclosure, when the vertical dark lines occur in display images of the display panel, forming at least four welds at an equal interval on the fan-out trace with the double-decked conducting wire structure to electrically connect the first and second conducting wires, stack-up in the fan-out trace and spaced by the insulating layer. In this way, the difference in impedance between the fan-out trace and a normal fan-out trace is reduced from a pre-restored ratio (i.e., 100%) to 20% or below regardless of breaking positions of a single-decked conducting wire in the fan-out traces. The present disclosure can solve technical problems that impedance increases due to a broken single-decked conducting wire in the fan-out traces with the double-decked conducting wire structure, thereby causing the vertical dark lines to occur in display images, causing display effects to be affected, and causing a quality level of display panel to be reduced, so that efficiency and a success rate of restoration of the vertical dark lines are improved effectively.

In order to understand the features and the technical content of the present disclosure further, please refer to the detailed explanation and the accompanying drawings of the present disclosure as follows. However, the accompanying drawings are merely for reference and explanation without limiting the present disclosure.

### BRIEF DESCRIPTION OF DRAWINGS

In order that the technical solutions and other beneficial effects of the present disclosure are apparent and easy to understand, specific embodiments of the present disclosure are described in conjunction with the accompanying drawings in detail below.

FIG. 1 is a schematic diagram of a method of restoring vertical dark lines of a display panel according to the present disclosure.

FIG. 2 is a schematic diagram of a fan-out trace with a double-decked conducting wire structure in a normal state.

FIG. 3 is a schematic diagram of the fan-out trace with the double-decked conducting wire structure while a single-decked film is broken.

FIG. 4 is a schematic diagram of the fan-out trace shown in FIG. 3 being restored through the method of restoring the vertical dark lines according to the present disclosure.

### DETAILED DESCRIPTION OF EMBODIMENTS

In order to explain the technical solutions and the effects of the present disclosure further, they will be described in conjunction with preferred embodiments and the accompanying drawings of the present disclosure in detail below.

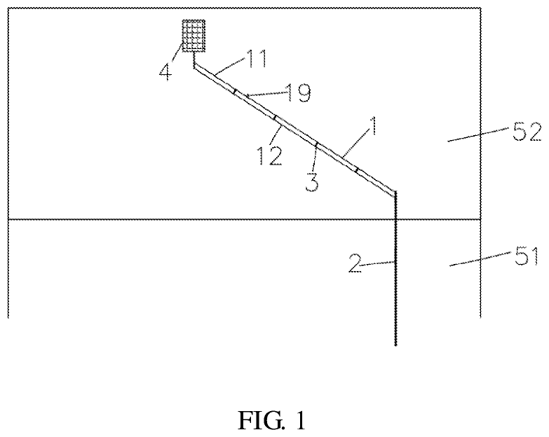

Please refer to FIG. 1, the present disclosure first provides a method of restoring vertical dark lines of a display panel, configured to restore the display panel whose the vertical dark lines due to a broken single-decked conducting wire in fan-out traces with a double-decked conducting wire structure. The display panel has at least one fan-out trace 1 with a double-decked conducting wire structure. The fan-out trace 1 includes a first conducting wire 11 and a second conducting wire 12 stack-up. An insulating layer 15 is disposed between the first and second conducting wires 11 and 12 to insulate and space the first and second conducting wires 11 and 12. One of the first and second conducting wires 11 and 12 has a gap 19. Two ends of the first conducting wire 11 are electrically connected to two ends of the second conducting wire 12 respectively to form two ends of the fan-out trace 1.

In the present disclosure, the method of restoring the vertical dark lines of the display panel includes:

Forming n welds 3 at an equal interval on the fan-out trace 1. The fan-out trace 1 is equally divided into n+1 line segments by the n welds 3, and the first and second conducting wires 11 and 12 are electrically connected at a location of each of the welds 3 through the welds 3, wherein n is a natural number greater than or equal to four. Relative to the fan-out trace 1 where the gap 19 exists due to a broken single-decked conducting wire, impedance of the welded fan-out trace 1 is significantly reduced, thereby solving technical problems that a loss of signals transmitted by the fan-out trace 1 increases when one of the first and second conducting wires 11 and 12 is broken due to film-forming foreign objects or other reasons, causing dark lines to occur in display images and causing display effects to be affected.

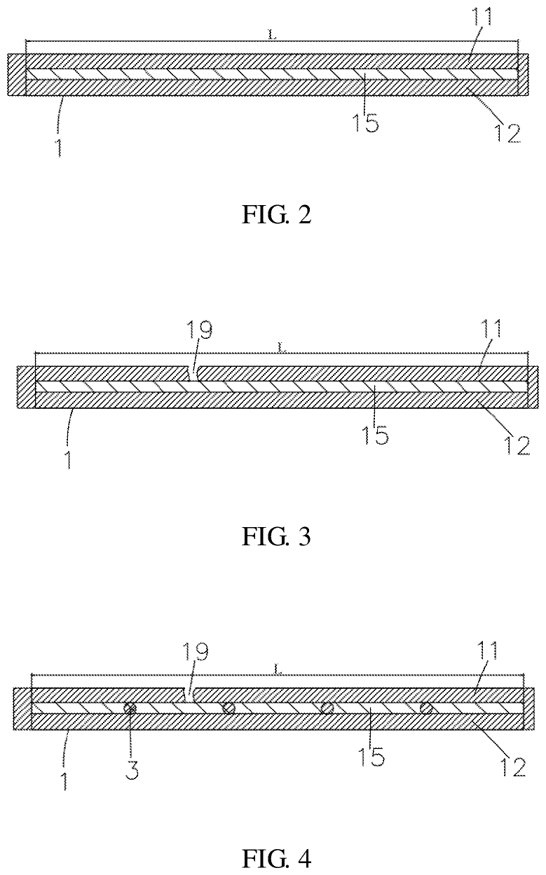

It needs to be stated that the design principle of the method of restoring the vertical dark lines of the display panel, in the present disclosure, is as follows: assuming that the lengths of the first and second conducting wires 11 and 12 are both L, the resistivities of the first and second conducting wires 11 and 12 are both p, and the areas of the first and second conducting wires 11 and 12 are both S, the resistance of the first and second conducting wires 11 and 12 is equal and calculated according to the formula: R=pL/S. As shown in FIG. 2, the resistance of the fan-out trace 1 in a normal state is calculated according to the formula: Ro=pL/S*1/2=0.5R. As shown in FIG. 3, when a single-decked film of the fan-out trace 1 (i.e., the first conducting wire 11 or the second conducting wire 12) is broken, the resistance of the fan-out trace 1 is calculated according to the formula: Rn=pL/S=R. That is, due to a broken first conducting wire 11 or a broken second conducting wire 12, the impedance of the fan-out trace 1 doubles, a difference ratio in impedance is 100%, and thus a loss of signals transmitted by the fan-out trace 1 increases, causing the vertical dark lines to occur in the display images and causing quality of display panel to degrade so that the display panel is discarded. As shown in FIG. 4, in the present disclosure, at least four welds 3 are formed on the fan-out trace 1 having a broken single-decked film. If four welds 3 are disposed on the fan-out trace 1, the resistance of the fan-out trace 1 is calculated according to the formula: Rs=pL/S*1/5+pL/S*4/5*1/2=0.6R, and the difference ratio in impedance decreases to 20% regardless of breaking positions of the first conducting wire 11 or the second conducting wire 12, in the fan-out trace 1. Thus, the problem of the vertical dark lines in the display images can be effectively improved so that quality of display panel can be prevented from degrading, and the display panel can be prevented from being discarded. Apparently, if at least four welds 3 are formed on the fan-out trace 1, the difference ratio in impedance will decrease to 20% or below further. However, comprehensively considering restoration effects and restoration efficiency, the present disclosure prefers to form four welds 3 on the fan-out trace 1.

Specifically, the welds 3 are formed through a laser-welding method.

Further, the step of forming the welds 3 through the laser-welding method includes: illuminating, by a laser, the fan-out trace 1, so that the insulating layer 15 illuminated by the laser is staved in, and the first and second conducting wires 11 and 12 illuminated by the laser melt to form the welds 3 in the insulating layer 15 staved in.

Specifically, the display panel is divided into a display area 51 and a joint area 52 located at the outside of the display area 51. A plurality of signal lines 2 are disposed in the display area 51. At least one pad 4 for externally connecting a driving chip is disposed in the joint area 52. The plurality of signal lines 2 include a plurality of gate lines and a plurality of data lines, which intersect with each other.

Specifically, the fan-out trace 1 is disposed in the joint area 52. One end of the fan-out trace 1 is connected to the gate lines or the data lines, and the other end of the fan-out trace 1 is connected to the pad 4.

Specifically, the first conducting wire 11 and the second conducting wire 12 are both metal wires.

Specifically, the first conducting wire 11 and the second conducting wire 12 are both wires made of aluminum.

For the display panel and the method of restoring the vertical dark lines of the display panel, provided in the present disclosure, forming at least four welds 3 at an equal interval on the fan-out trace 1 with the double-decked conducting wire structure to electrically connect the first and second conducting wires 11 and 12, stack-up in the fan-out trace 1 and spaced by the insulating layer 15. In this way, the difference in impedance between the fan-out trace 1 and a normal fan-out trace is reduced from a pre-restored ratio (i.e., 100%) to 20% or below regardless of breaking positions of a single-decked conducting wire in the fan-out trace 1. The present disclosure can solve technical problems that impedance increases due to a broken single-decked conducting wire in the fan-out trace 1 with the double-decked conducting wire structure, thereby causing the vertical dark lines to occur in display images, causing display effects to be affected, and causing a quality level of display panel to be reduced, so that efficiency and a success rate of restoration of the vertical dark lines are improved effectively.

The present disclosure further provides a display panel, made using the above method of restoring the vertical dark lines of the display panel, which can solve technical problems that impedance increases due to a broken single-decked conducting wire in the fan-out trace 1 with the double-decked conducting wire structure, thereby causing the vertical dark lines to occur in display images, causing display effects to be affected, and causing a quality level of display panel to be reduced.

For the display panel and the method of restoring the vertical dark lines of the display panel, provided in the present disclosure, when the vertical dark lines occur in display images of the display panel, forming at least four welds at an equal interval on the fan-out trace with the double-decked conducting wire structure to electrically connect the first and second conducting wires, stack-up in the fan-out trace and spaced by the insulating layer. In this way, the difference in impedance between the fan-out trace and a normal fan-out trace is reduced from a pre-restored ratio (i.e., 100%) to 20% or below regardless of breaking positions of the single-decked conducting wire in the fan-out traces. The present disclosure can solve technical problems that impedance increases due to a broken single-decked conducting wire in the fan-out traces with the double-decked conducting wire structure, thereby causing the vertical dark lines to occur in display images, causing display effects to be affected, and causing a quality level of display panel to be reduced, so that efficiency and a success rate of restoration of the vertical dark lines are improved effectively.

A person of ordinary skill in the art is able to make modifications or changes corresponding to the foregoing description based on the technical solutions and the technical ideas of the present disclosure, and all of these modifications and changes should be within the protective scope of the appended claims of the present disclosure.

What is claimed is:

1. A method of restoring vertical dark lines of a display panel having at least one fan-out trace with a double-decked conducting wire structure, the at least one fan-out trace comprising a first conducting wire and a second conducting wire stack-up, an insulating layer being disposed between the first and second conducting wires to insulate and space the first and second conducting wires, one of the first and second conducting wires having a gap, the method comprising:
forming n welds at an equal interval on the at least one fan-out trace, wherein the at least one fan-out trace is equally divided into n+1 line segments by the n welds, wherein the first and second conducting wires are electrically connected at a location of each of the n welds through the n welds, and wherein n is a natural number greater than or equal to four.

2. The method of claim 1, wherein four welds are formed on the at least one fan-out trace.

3. The method of claim 1, wherein the n welds are formed through a laser-welding method.

4. The method of claim 3, wherein the step of forming the n welds through the laser-welding method comprises: illuminating, by a laser, the at least one fan-out trace, so that the insulating layer illuminated by the laser is staved in, and the first and second conducting wires illuminated by the laser melt to form the n welds in the insulating layer staved in.

5. The method of claim 1, wherein two ends of the first conducting wire are electrically connected to two ends of the second conducting wire respectively to form two ends of the at least one fan-out trace.

6. The method of claim 5, wherein the display panel is divided into a display area and a joint area located at the outside of the display area, wherein a plurality of signal lines are disposed in the display area, wherein at least one pad for externally connecting a driving chip is disposed in the joint area, and wherein the plurality of signal lines comprise a plurality of gate lines and a plurality of data lines, which intersect with each other.

7. The method of claim 6, wherein the at least one fan-out trace is disposed in the joint area, wherein one end of the at least one fan-out trace is connected to the plurality of gate lines or the plurality of data lines, and wherein the other end of the at least one fan-out trace is connected to the at least one pad.

8. The method of claim 1, wherein the first conducting wire and the second conducting wire are both metal wires.

9. The method of claim 8, wherein the first conducting wire and the second conducting wire are both wires made of aluminum.

10. A display panel, made using a method of restoring vertical dark lines of the display panel having at least one fan-out trace with a double-decked conducting wire structure, the at least one fan-out trace comprising a first conducting wire and a second conducting wire stack-up, an insulating layer being disposed between the first and second conducting wires to insulate and space the first and second conducting wires, one of the first and second conducting wires having a gap, wherein the method of restoring vertical dark lines of the display panel comprises:
forming n welds at an equal interval on the at least one fan-out trace, wherein the at least one fan-out trace is equally divided into n+1 line segments by the n welds, wherein the first and second conducting wires are electrically connected at a location of each of the n welds through the n welds, and wherein n is a natural number greater than or equal to four.

11. The display panel of claim 10, wherein four welds are formed on the at least one fan-out trace.

12. The display panel of claim 10, wherein the n welds are formed through a laser-welding method.

13. The display panel of claim 12, wherein the step of forming the n welds through the laser-welding method comprises: illuminating, by a laser, the at least one fan-out trace, so that the insulating layer illuminated by the laser is staved in, and the first and second conducting wires illuminated by the laser melt to form the n welds in the insulating layer staved in.

14. The display panel of claim 10, wherein two ends of the first conducting wire are electrically connected to two ends of the second conducting wire respectively to form two ends of the at least one fan-out trace.

15. The display panel of claim 14, wherein the display panel is divided into a display area and a joint area located at the outside of the display area, wherein a plurality of signal lines are disposed in the display area, wherein at least one pad for externally connecting a driving chip is disposed in the joint area, and wherein the plurality of signal lines comprise a plurality of gate lines and a plurality of data lines, which intersect with each other.

16. The display panel of claim 15, wherein the at least one fan-out trace is disposed in the joint area, wherein one end of the at least one fan-out trace is connected to the plurality of gate lines or the plurality of data lines, and wherein the other end of the at least one fan-out trace is connected to the at least one pad.

17. The display panel of claim 10, wherein the first conducting wire and the second conducting wire are both metal wires.

18. The display panel of claim 17, wherein the first conducting wire and the second conducting wire are both wires made of aluminum.
